(19) United States
(12) Patent Application Publication
(10) Pub. No.: US 2025/0291985 A1
(43) Pub. Date: Sep. 18, 2025

(54) METHODS, SYSTEMS, AND APPARATUS TO IMPROVE SIMULATIONS OF GATE LEVEL NETLISTS

(71) Applicant: Texas Instruments Incorporated, Dallas, TX (US)

(72) Inventors: Netanel Miller, Ramat-Gan (IL); Eilon Tabachnik, Herzliya (IL)

(21) Appl. No.: 18/606,942

(22) Filed: Mar. 15, 2024

(51) Int. Cl. G06F 30/327

(52) U.S. Cl. CPC G06F 30/327

(57) ABSTRACT

Systems, apparatus, articles of manufacture, and methods are disclosed to improve simulations of gate level netlists. An example apparatus includes interface circuitry to obtain register transfer level code indicative of an operation of an integrated circuit, machine-readable instructions, and programmable circuitry to at least one of instantiate or execute the machine-readable instructions to obtain a gate level netlist corresponding to the integrated circuit, the gate level netlist including modules in the integrated circuit and connections between the modules, obtain a first probe, the first probe representing a first location within the gate level netlist at which to monitor behavior, identify a root module that includes an output configured to determine a signal at the first location, and generate a second probe to replace the first probe representing a second location within the gate level netlist closer to the output of the root module than the first probe.

### TECHNICAL FIELD

This disclosure relates generally to design and verification of integrated circuits and, more particularly, to methods, systems, and apparatus to improve simulations of gate level netlists of integrated circuit devices.

### BACKGROUND

An integrated circuit is an assembly of circuits on one, usually small, piece of semiconductor material. Integrated circuits are important because they facilitate miniaturization of electronic devices, such as computers, tablets, cell phones, etc. For example, integrated circuits allow the integration of thousands to billions of electronic components on a single small chip, making the electronic devices portable and convenient. Consumers have developed a reliance on the performance, efficiency, and convenience of electronic devices. Thus, a need has increased for smaller, faster, and better integrated circuits. Therefore, it has become important to design and build efficient and reliable integrated circuits.

### BRIEF DESCRIPTION OF THE DRAWINGS

FIG. 1 is a block diagram of an example simulation environment in which example synthesis circuitry operates to simulate and verify a gate level netlist.

FIG. 2 is a block diagram of an example implementation of the probe selection controller of FIG. 1.

FIG. 3 is an example simulated gate level netlist of a portion of a system on a chip (SoC).

FIGS. 4-5 are flowcharts representative of example machine readable instructions and/or example operations that may be executed, instantiated, and/or performed by example programmable circuitry to implement the probe selection controller 126 of FIG. 2.

FIG. 6 is a block diagram of an example processing platform including programmable circuitry structured to execute, instantiate, and/or perform the example machine readable instructions and/or perform the example operations of FIGS. 4-5 to implement the probe selection controller 126 of FIG. 2.

FIG. 7 is a block diagram of an example implementation of the programmable circuitry of FIG. 6.

FIG. 8 is a block diagram of another example implementation of the programmable circuitry of FIG. 6.

In general, the same reference numbers will be used throughout the drawing(s) and accompanying written description to refer to the same or like parts. The figures are not necessarily to scale.

### DETAILED DESCRIPTION

Designing integrated circuits (ICs) is meticulous. Synthesis tools provide a way for design engineers to simplify the design of ICs. Synthesis is the process of converting Register Transfer Level (RTL) code into a gate level netlist (GLN). RTL code is code that captures a desired behavior of a circuit design. RTL code is written in hardware description languages (e.g., Verilog, VHDL, etc.) and serves as one of the inputs to the synthesis tool. A second input to the synthesis tool is a technology library. A technology library is a collection of standard cells, gates, and other components specific to the target technology (e.g., the target circuitry to be implemented in the IC). A third input to the synthesis tool is a constraint file. A constraint file guides the synthesis tool, providing additional information and specifications for optimizing the generation of the GLN. In some examples, the constraint file includes timing constraints, power targets, and area requirements of the IC.

A GLN is the output of the synthesis tool. The GLN is the netlist view of the IC, including a complete connection list of gates with full functional and timing behavior. A gate level netlist is a list of electronic components (e.g., modules) in a circuit and a list of the nodes to which those components are connected. In some examples, the netlist is a textual catalog of the electronic components and the connections that go with them.

During synthesis, the synthesis tool executes an elaboration process after obtaining the inputs. The elaboration process reads the RTL code and converts the RTL code into modules as per its logical hierarchy. A module represents a design unit that implements certain behavioral characteristics of the design of the IC. For example, any parameters, logic conditions, etc., contained in the RTL are inferred when the module is created. In some examples, a module represents a circuit component (e.g., a logic gate, a comparator, etc.), an entire circuit (e.g., analog-to-digital converter, transmitter, receiver, etc.), and/or the IC as a whole. For example, a top-level module describes the IC as a whole, submodules describe circuits included in the design of the IC, and low-level module describes circuit components within a circuit on the IC. Each module is described in hardware description language (HDL). The naming conventions for modules is such that it is identifiable in a large RTL file. For example, a hierarchical naming convention may be used, where a portion of HDL, say, Register W fits within a subset of HDL called for example, C, within a part of a high level function, say, B, which in turn fits within a larger contextual portion of HDL performing that high level function A, and which in turn fits within an even larger contextual portion of an even higher level function, for example, bus controller BC. Thus, the identification of Register W could be “BC.A.B.C.RegisterW.” Other naming conventions can also be used, although a hierarchical approach provides clarity and simplicity.

After RTL is converted into modules, the synthesis tool maps the modules and corresponding logic to cells in the technology library. For example, the gates are mapped to actual technology-dependent logic gates accessible in technology libraries.

After elaboration, the synthesis tool optimizes the logic and design of the RTL based on the constraints indicated in the constraint file. For example, during synthesis, the synthesis tool may optimize the design of the IC based on the constraints. In some examples, this includes reducing a number of logic gates, reducing an area of the target IC, optimizing power, etc. Although these optimizations are beneficial, the optimization causes changes at the output of the synthesis (e.g., changes of the RTL code to the GLN). For example, wire logic may change, signals may have a reverse polarity, signals may merge, signals may disconnect, etc. These optimization changes are present in the GLN.

A GLN undergoes simulation in a development environment. For example, a development environment simulates a GLN (and RTL) to determine and analyze the behavior of the target IC. As used herein, gate level simulation (GLS) is the simulation of a gate level netlist (GLN). When running Gate Level Simulations (GLS) in the development (DV) environment, changes in logic and design of the RTL code 114 and changes that occur each time synthesis is rerun due to optimizations during the synthesis process can cause changes in the GLN being tested. In some examples, these changes cause issues when testing and analyzing the GLN. For example, the DV environment may lack integrity (e.g., unity, cohesion, etc.) over time due to wire connectivity (e.g., interconnections, nets, wires) being disconnected during optimization, wires merging, wires not having the same polarity, etc. As such, a subsequent DV environment may not be able to accurately sample (e.g., probe, test, analyze, etc.) the same wires as a previous iteration of the DV environment, because those wire names may represent different functionality.

In some examples, the DV environment generates initial probing points during simulation of the RTL code to monitor and/or analyze the actual (e.g., logical) behavior of the RTL code at specified locations (e.g., the behavior of the outputs or inputs of modules). Probes are logical flags placed into the hardware description language where something of interest is happening and a value is to be measured at a particular time. For example, a DV environment creates HDL statements (e.g., logical flags, probes) and/or GLN probe points and uses them when simulating RTL code and/or a GLN. In some examples, the probes have a hierarchical naming convention to enable identification of the probes in the HDL and/or differentiate the probes from the modules. The actual behavior observed at the probe point may be compared to the intended behavior of the IC, as indicated by the RTL. The initial probing points are additionally used to monitor and/or analyze the actual (e.g., physical) behavior of the GLN. Such monitoring enables engineers to determine whether the GLS is or is not operating as intended. Generally, engineers had to manually debug the GLS failures by manually identifying inverted and/or disconnected signals (and/or the associated wires) and then changing a respective probing point (e.g., a test point) location in the code and/or the expected behavior. Manually searching for the signals and changing the probing points took a considerable amount of time. Additionally, manually searching for the signals and changing the probing points may take time away from the engineers to analyze the real issues in the DV environment.

Therefore, many examples disclosed herein reduce or eliminate the manual debugging process of the probing points by automatically identifying alternative locations for probing points in the GLS and translating an expected result at an initial probe point into an expected result at the alternative location. For example, examples disclosed herein use the RTL code and GLN to modify probing points in the DV environment. In examples disclosed herein, the probing points are changed to locations that have lower probabilities of being affected by optimization changes and be more consistent across iterations of the design. Therefore, examples disclosed herein significantly reduce the amount of time spent on debugging a GLS and producing the target IC.

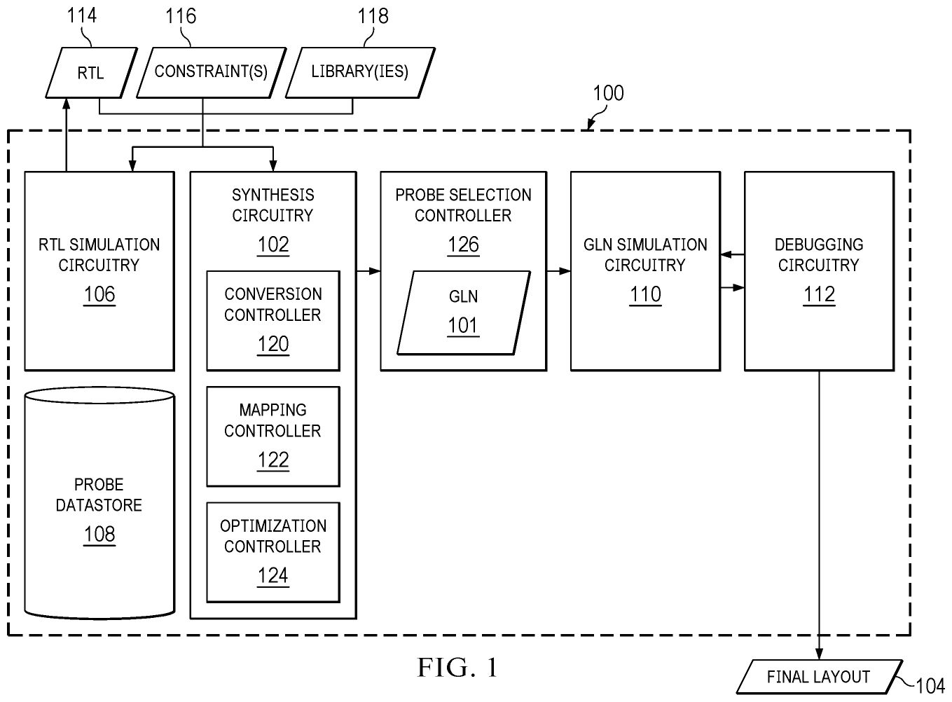

FIG. 1 is a block diagram of an example development environment 100 in which example synthesis circuitry 102 operates to simulate and verify a gate level netlist (GLN) 101, example GLN simulation circuitry 110 operates to simulate the GLN 101, and example debugging circuitry 112 operates to generate a final layout 104. The example development environment 100 includes example RTL simulation circuitry 106, the example synthesis circuitry 102, an example probe datastore 108, example GLN simulation circuitry 110, example debugging circuitry 112, and an example probe selection controller 126.

In FIG. 1, the example RTL simulation circuitry 106 obtains inputs for simulating and verifying RTL code 114. For example, the RTL simulation circuitry 106 obtains RTL code 114, constraint(s) 116, and library(ies) 118. The example RTL simulation circuitry 106 is run in the example development environment 100. The example RTL simulation circuitry 106 simulates the RTL code 114 to check and verify the logical operation of a circuit design.

For example, the RTL code 114 is code that captures a desired or intended behavior (e.g., operation) of a circuit design, written in hardware description languages, and synthesizable to technology specific gate level netlist (e.g., GLN 101). As used herein, the intended behavior and/or intended operation of an IC is the operation of an IC created according to the RTL code 114 and the final layout 104. The example RTL simulation circuitry 106 executes and/or runs the RTL code 114 in the development environment 100 to enable modification and/or verification of the logical parameters of the RTL code 114. In some examples, the development environment 100 enables such modification and/or verification by generating and inserting initial probes in the RTL code 114. The initial probes provide a development engineer with insight into how the logical parameters of the RTL code 114 are working. In FIG. 1, the example development environment 100 stores the initial probes in the example probe datastore 108.

The example constraint(s) 116 is a (are) requirement(s) that the development environment 100 has to ensure the final layout 104 meets and/or represents, including timing constraints, power constraints, area size constraints, configuration constraints, etc. The example library(ies) 118 is a (are) technology library(ies) that include(s) standard cells, gates, and other components specific to the target technology. The example library(ies) 118 is/are used to synthesize the RTL code 114 and generate the GLN 101, by mapping abstracted and/or conceptual designs of an IC to actual technology (e.g., circuit components) that would implement such conceptual designs.

As illustrated in FIG. 1, the RTL simulation circuitry 106 modifies the RTL code 114 until the RTL code 114 is operating as intended and, thus, has been verified. In some examples, the RTL simulation circuitry 106 obtains the inputs (e.g., RTL code 114, constraint(s) 116, and library(ies) 118) from a development engineer, such as an integrated circuit (IC) design engineer who develops and designs ICs. In some examples, the engineer imports and/or uploads the inputs to the development environment 100.

In FIG. 1, the example synthesis circuitry 102 is a synthesis tool to synthesize the RTL code 114 and generate the GLN 101. The example synthesis circuitry 102 includes an example conversion controller 120, an example mapping controller 122, and an example optimization controller 124. The example synthesis circuitry 102 may be instantiated (e.g., creating an instance of, bring into being for any length of time, materialize, implement, etc.) by programmable circuitry such as a Central Processor Unit (CPU) executing first instructions.

In FIG. 1, the example conversion controller 120 obtains RTL code 114, verified by the example RTL simulation circuitry 106, and converts the RTL code 114 into modules per the modules' logical hierarchy. For example, the conversion controller 120 converts codes and arithmetic operators (e.g., addition, subtraction, division, multiplication, etc.) into modules corresponding to basic logic gates, flops, counters, switches, etc. In some examples, the conversion controller 120 converts the RTL files into modules by analyzing the design hierarchy then executing initial commands in the RTL 114. The example conversion controller 120 detects asynchronous reset (e.g., the signal used to initialize the IC and force the IC into a known state for simulation). The example conversion controller 120 converts decision tree(s) to multiplexer module(s). The example conversion controller 120 converts synchronous code to a level triggering device module, a flip-flop module, etc. The example conversion controller 120 detects finite state machine (FSM) logic and extracts a number of input/output bits and state bits and then converts the FSM logic to basic logic (e.g., Boolean logic). The example conversion controller 120 generates memory cells and maps the memory cells to basic logic (e.g., Boolean logic). In some examples, the conversion controller 120 uses the constraint(s) 116 to add additional components and/or features to the modules. For example, the conversion controller 120 adds power domains, level shifters, power switches, retention flops, and/or any other component/feature that a design engineer required for the target (e.g., hypothetical) IC.

When the RTL code 114 and the constraint(s) 116 have been converted, the example conversion controller 120 notifies the example mapping controller 122. For example, the conversion controller 120 triggers the mapping controller 122 to map the modules and corresponding logic to a technology library(ies) 118.

In FIG. 1, the example mapping controller 122 maps the modules to the technology library(ies) 118. For example, when the RTL code 114 and the constraint(s) 116 have been converted into modules (e.g. a logical Boolean representation), the mapping controller 122 maps the modules and corresponding logic with technology dependent cells from the library(ies) 118. In some examples, cell mapping is dependent on the constraint(s) 116. Therefore, the example mapping controller 122 considers the constraint(s) 116 when mapping the modules to the library(ies) 118.

In FIG. 1, the example optimization controller 124 optimizes the logic and design of the converted RTL code 114. In some examples, optimizing the logic of the converted RTL code 114 includes, but it not limited to, detecting identical cells and removing them, performing constant folding (e.g., eliminating expressions that calculate a value that can already be determined before code execution), consolidating multiplexers, reducing inputs, removing flip-flops having a constant value, reducing word size of cells, and removing unused cells and wires. In some examples, optimizing the design of the converted RTL code 114 includes, but is not limited to, optimizing power, optimizing area, and reducing an amount of worst negative slack (e.g., reducing how much timing is missed through a critical path through the IC design) and total negative slack (e.g., the sum over all paths through the IC design of how much paths miss timing).

In some examples, the optimization controller 124 outputs the GLN 101 after optimizing is complete. For example, the optimization controller 124 may perform optimization of the converted RTL code 114, compile the optimized RTL code 114, and generates the GLN 101. The GLN 101 specifies a set of gates and/or other circuit devices found in the libraries 118 and a set of interconnections (nets) between the circuit devices in order to implement the behaviors defined in the RTL 114 and satisfy the constraints 116. The GLN 101 may also specify properties of the gates and circuit devices such as device sizing, type, placement, etc. As used herein, gates and circuit devices are referred to as modules.

In FIG. 1, the example GLN simulation circuitry 110 simulates the GLN 101, using the RTL code 114, the constraint(s) 116, the library(ies) 118, and a set of probing points to create a GLS. The example GLN simulation circuitry 110 operates in the development environment 100 to simulate the GLN 101. Simulating the GLN 101 refers to modeling the physical IC on a computer to study how the physical IC would operate in a real-world scenario. In order to analyze and/or study how the physical IC would operate, the example GLN simulation circuitry 110 monitors probing points in the GLS by reporting behaviors at the probing points in various different operating conditions. The probing points provide a development or test engineer a way to see how the GLS is actually operating. For example, the GLN simulation circuitry 110 may record and monitor values of signals (e.g., logic 1s, logic 0s, voltage, current, resistance, power, temperature, etc.) at the input and outputs of gates or other circuit devices in the GLN 101 and display the values on a user interface. In some examples, the GLN simulation circuitry 110 compares the simulated operation (e.g., as indicated by the probes) of the GLN 101 to the intended operation of the IC (e.g., as indicated by the RTL code 114, a user-provided specification, or other golden model).

The GLN simulation circuitry 110 monitors probing points in the GLN 101. For example, the GLN simulation circuitry 110 may use and/or select initial probes stored in the probe datastore 108. However, in some examples, the initial placements of the initial probes may be incorrect and/or not optimal due to optimization changes. For example, while the initial probes are stable for monitoring the RTL code 114, they may not be stable for monitoring the GLN 101 due to optimization changes in wire connectivity between modules. For example, changes in device placement between iterations of synthesis may cause different buffering along a long wire. As another example, changes in the logic gates of a synthesized block between iterations of synthesis may cause a different value or polarity to be driven along a particular wire. Therefore, the example probe selection controller 126 may modify the placement of the initial or automatic probes to alternative locations. The probe selection controller 126 may also translate intended operation at an initial placement into an intended operation at an alternative location. For example, if an initial probe point is at the output of an inverter that may or may not be present in a given iteration of a GLN 101 depending on downstream logic, the probe selection controller 126 may select an alternative location for the probe point that is before the inverter and thus invert the intended operation used to determine whether the signal at the alternative location meets the intended operation.

Due to the probe selection controller 126, a development engineer or test engineer does not have to identify the best probing points in the GLS. Instead, the GLN simulation circuitry 110 can position the probing points at the location selected by the probe selection controller 126 and the engineer can monitor the probes. Accordingly, engineers can utilize their time debugging the GLS rather than selecting better or new probing points.

In FIG. 1, the example probe selection controller 126 determines alternative locations of probing points in the GLN 101. Probes are assigned to outputs and/or inputs of a simulated GLN (GLS) to test and monitor whether the GLS is operating as intended. For example, if the RTL code 114 specifies that when A=B, a specific output should be equal to 1, then the probe should read as equal to 1 when A=B, and 0 when A≠B. Due to changes in the GLN 101 during optimization, signals A and B and even the output may be inverted or may not exist in a given version the GLN 101. Accordingly, the example probe selection controller 126 may identify and select initial probe points that may not exits and modify their places to locations or points that are likelier to exist and where there is a lower probability of a reversed polarity or a floating location (floating path). Probes are placed on wire connectivity (e.g., nets, interconnections, wires, conductors, signal paths, inputs, outputs, etc.) and, thus, the example probe selection controller 126 identifies locations or points on the wire connectivity with a low probability that the location or point will be floating or have reverse polarity.

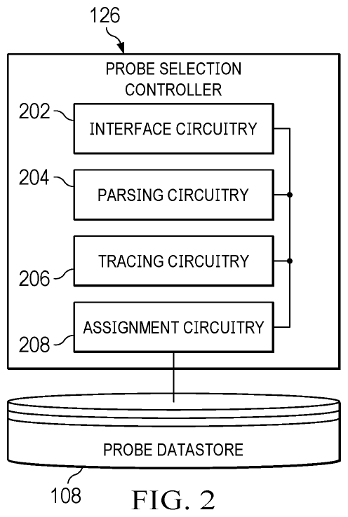

In some examples, the probe selection controller 126 modifies the location of the probes based on parsing and analyzing the RTL 114 code to find a root source for each wire connectivity. The root source may be a module which has a root output, where the root output is driven internally from fixed (e.g., hardcoded) logic or a register. For example, a root output provides the first output in a series of two or more outputs. In some examples, a root module is a splitter and a non-root module is an inverter located out the output of the splitter. Therefore, the splitter provides the root output for the wire connectivity that includes the output of the splitter and the output of the inverter. The example probe selection controller 126 is described in further detail below in connection with FIG. 2.

In FIG. 1, the example probe datastore 108 stores initial probes from the development environment 100 and alternative probe points from the probe selection controller 126. The example probe datastore 108 may be accessed by the example GLN simulation circuitry 110 to obtain alternative probe points. The example probe datastore 108 may be implemented by a volatile memory (e.g., a Synchronous Dynamic Random Access Memory (SDRAM), Dynamic Random Access Memory (DRAM), RAMBUS Dynamic Random Access Memory (RDRAM), etc.) and/or a non-volatile memory (e.g., flash memory). The example probe datastore 108 may additionally or alternatively be implemented by one or more double data rate (DDR) memories, such as DDR, DDR2, DDR3, DDR4, mobile DDR (mDDR), etc. The example probe datastore 108 may additionally or alternatively be implemented by one or more mass storage devices such as hard disk drive(s), compact disk (CD) drive(s), digital versatile disk (DVD) drive(s), solid-state disk drive(s), etc. While in the illustrated example the probe datastore 108 is illustrated as a single datastore, the probe datastore 108 may be implemented by any number and/or type(s) of datastores. Furthermore, the data stored in the example probe datastore 108 may be in any data format such as, for example, binary data, comma delimited data, tab delimited data, structured query language (SQL) structures, etc.

In FIG. 1, the example debugging circuitry 112 compares the behavior measured at the probe points in the GLN 101 against the expected behavior based on the RTL 114 to debug the GLS and may make any necessary corrections to the GLN 101. For example, the debugging circuitry 112 scans the GLS to assist the engineer in identifying issues in the design and devices. In some examples, the debugging circuitry 112 scans the GLS for timing delays, devices stuck at faults, etc. In some examples, the debugging circuitry 112 generates a report of the issues identified. In some examples, the debugging circuitry 112 notifies the engineer, via a user interface, of the issues identified. In some examples, the debugging circuitry 112 executes scans upon a trigger (e.g., in response to receiving a command). In other examples, the debugging circuitry 112 executes a scan automatically when the GLS is generated. As illustrated in FIG. 1, when the debugging circuitry 112 identifies issues and the engineer corrects the issues, the GLN simulation circuitry 110 simulates the GLN 101 again. This process is repeated until the GLN 101 has been fully debugged and verified. As such, the example GLN simulation circuitry 110 and the example debugging circuitry 112 operate to check the physical parameters of the GLN 101.

When the engineer determines that no issues are present in the GLS (e.g., debugging was successful), the GLN simulation circuitry 110 generates the final layout 104. In some examples, the final layout 104 is used by engineers to create a “master blueprint” of the target IC. The debugged GLS allows the test engineers to finalize the gate level netlist 101. The final version of the gate level netlist 101 may be used to generate a detailed layout of the target IC that includes placed and routed transistors, circuits, and other components, referred to as the final layout 104.

FIG. 2 is a block diagram of an example implementation of the probe selection controller 126 of FIG. 1 to select probing points. The probe selection controller 126 of FIG. 2 may be instantiated (e.g., creating an instance of, bring into being for any length of time, materialize, implement, etc.) by programmable circuitry such as a Central Processor Unit (CPU) executing first instructions. Additionally or alternatively, the probe selection controller 126 of FIG. 2 may be instantiated (e.g., creating an instance of, bring into being for any length of time, materialize, implement, etc.) by (i) an Application Specific Integrated Circuit (ASIC) and/or (ii) a Field Programmable Gate Array (FPGA) structured and/or configured in response to execution of second instructions to perform operations corresponding to the first instructions. It should be understood that some or all of the circuitry of FIG. 2 may, thus, be instantiated at the same or different times. Some or all of the circuitry of FIG. 2 may be instantiated, for example, in one or more threads executing concurrently on hardware and/or in series on hardware. Moreover, in some examples, some or all of the circuitry of FIG. 2 may be implemented by microprocessor circuitry executing instructions and/or FPGA circuitry performing operations to implement one or more virtual machines and/or containers.

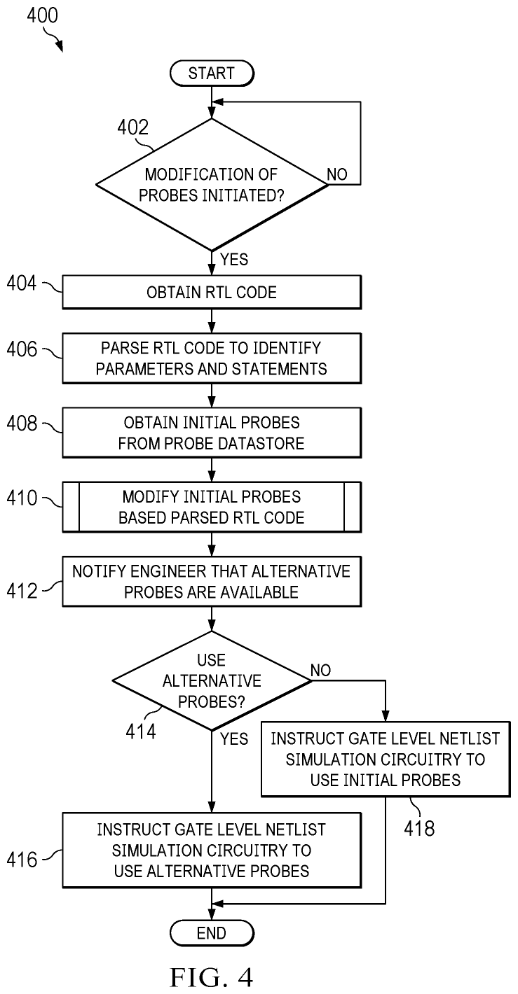

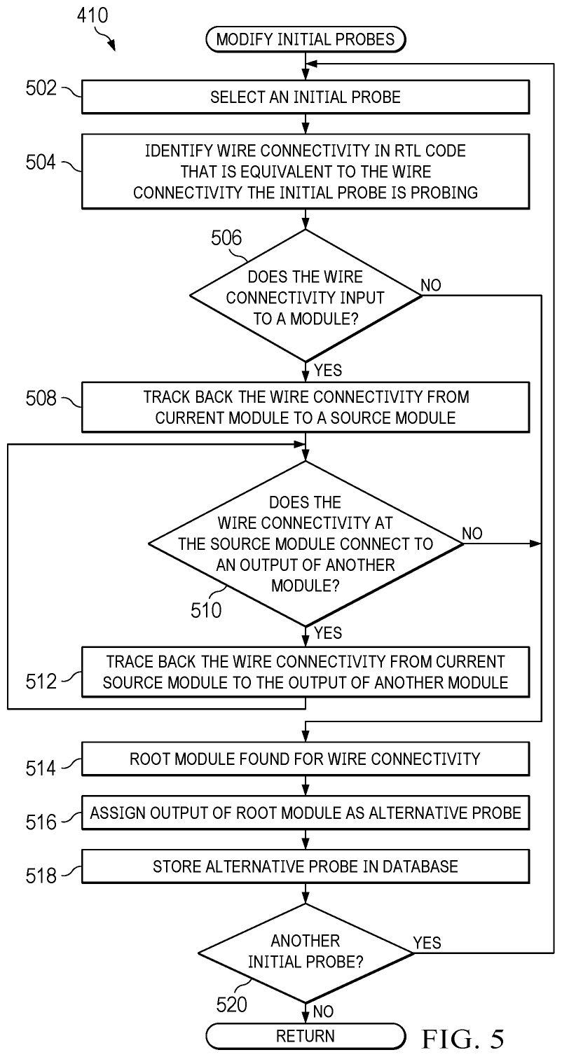

The example probe selection controller 126 includes example interface circuitry 202, example parsing circuitry 204, example tracing circuitry 206, and example assignment circuitry 208. In some examples, the interface circuitry 202 is instantiated by programmable circuitry executing interface instructions and/or configured to perform operations such as those represented by the flowcharts of FIGS. 4-5. In some examples, the parsing circuitry 204 is instantiated by programmable circuitry executing parsing instructions and/or configured to perform operations such as those represented by the flowcharts of FIGS. 4-5. In some examples, the tracing circuitry 206 is instantiated by programmable circuitry executing tracing instructions and/or configured to perform operations such as those represented by the flowcharts of FIGS. 4-5. In some examples, the assignment circuitry 208 is instantiated by programmable circuitry executing assignment instructions and/or configured to perform operations such as those represented by the flowcharts of FIGS. 4-5.

The example probe selection controller 126 of FIGS. 1 and 2 includes the interface circuitry 202 to obtain inputs used for selecting probe points. The inputs used for selecting probe points include RTL code 114, the GLN 101, and initial probes. The example interface circuitry 202 receives the GLN 101 as a trigger to begin the modification and/or selection of alternative probes. In some examples, the interface circuitry 202 communicates the inputs with the parsing circuitry 204, the tracing circuitry 206, the assignment circuitry 208, and/or the probe datastore 108 (FIG. 1).

The example probe selection controller 126 of FIGS. 1 and 2 includes the example parsing circuitry 204 to extract information from the inputs representative of parameters and statements. For example, the parsing circuitry 204 parses and/or extracts the RTL code 114. When the parsing circuitry 204 parses the RTL code 114, the parsing circuitry 204 obtains statements and parameters corresponding to modules (e.g., gates and other circuit devices). In some examples, the tracing circuitry 206 uses the statements and parameters to identify a root module for an initial probe. In some examples, parameters and statements of the RTL code 114 and the initial probes of the development environment 100 provide a lower level view of the GLN 101. The example parsing circuitry 204 may implement any type of parsing algorithm.

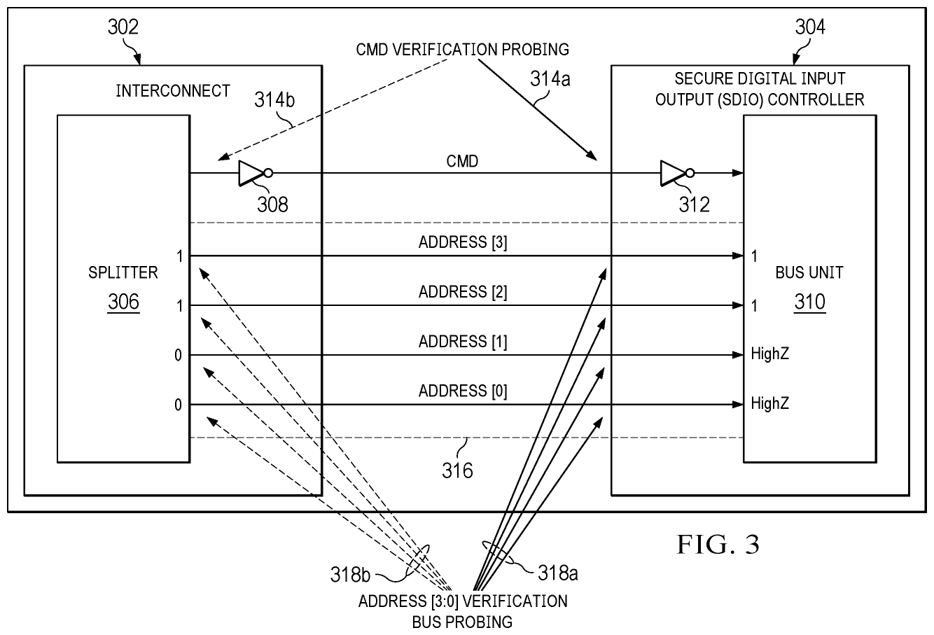

The example probe selection controller 126 of FIGS. 1 and 2 includes the example tracing circuitry 206 to trace (e.g., iterate) the RTL code 114, using the parsed inputs, to identify root modules generating initial data outputs for wire connectivity (e.g., connections, signal paths, wires, conductors, etc.). The example tracing circuitry 206 identifies a wire connectivity (e.g., connections, signal paths, wires, conductors, etc.) and determines whether the wire connectivity is an output of a root module, or whether it is an output of a non-root module. As described above and reiterated here for convenience, a root module may be a gate or circuit device which has a root output, where the root output is driven internally from fixed (e.g., hardcoded) logic or a register. As used herein, a non-root module may be a gate or circuit device which receives an input from a root module and provides an output to another non-root module. The example tracing circuitry 206 selects a wire connectivity to trace based on an initial probe. For example, the GLN 101 includes initial or automatically placed probes, and the probe selection controller 126 automatically modifies the placement of the initial probes to alternative locations. The example tracing circuitry 206 selects an initial probe and uses RTL code 114 to identify the module having a corresponding input or output. For example, the example tracing circuitry 206 identifies a statement in the RTL code 114 matching a name of the initial probe. An initial probe has a name, where the name defines the wire connectivity (input, location, signal, wire, etc.) of the initial probe. For example, probe name “module1_inputbus” indicates that the initial probe is probing the input bus of module 1. Therefore, the example tracing circuitry 206 identifies the input or output of module being tested (e.g., probed). In some examples, the tracing circuitry 206 then iterates through the parsed RTL code 114 to identify the root source (root module) of the input or output. In some examples, the tracing circuitry 206 traces the wire connectivity in the GLN 101 back to the root source of the input or output. The operation of the example tracing circuitry 206 is described below in connection with FIG. 3.

FIG. 3 is an example simulated gate level netlist (GLS) 300 of a portion of a system on a chip (SoC). The GLS 300 is a schematic illustration of an SoC created according to RTL code and a final layout. The example GLS 300 of the SoC includes an example interconnect block 302 and an example secure digital input output (SDIO) controller 304. The example interconnect block 302 is a component that is to manage communication and data exchange between various subsystems, modules, and components within the SoC. The example interconnect block 302 may be a synthesizable set of logic and includes an example splitter 306, which may itself be a hardcoded or synthesizable set of logic. The interconnect block 302 also includes an example first logic gate 308 that is a product of the synthesis of the RTL code that defines the interconnect block 302. The example SDIO controller 304 is an interface for input or output devices. For example, the SDIO controller 304 is to interface devices (e.g., modems) to hosts (e.g., processors). The example SDIO controller 304 may be a synthesizable set of logic and includes an example bus unit 310 which may itself be a hardcoded or synthesizable set of logic. The SDIO controller 304 also includes an example second logic gate 312 that is the product of the RTL code that defines the SDIO controller 304. The example interconnect block 302 and the example SDIO controller 304 may include a plurality of devices to manage the communication and data exchange and to interface input or output devices. However, for the purpose of describing the example tracing circuitry 206 of FIG. 2, the example splitter 306, the example first logic gate 308, the example bus unit 310, and the example second logic gate 312 are illustrated.

In FIG. 3, the example splitter 306 is to route data, in parallel, between multiple endpoints. For example, the splitter 306 is to divide, duplicate, and/or direct data flows to one or more destinations. In this example, the splitter 306 is to communicate at least one or more data flows to the bus unit 310 of the SDIO controller 304. For example, the splitter 306 is to provide a command (CMD) and a corresponding memory address bus 316 to the bus unit 310. In this example, the memory address bus 316 output by the splitter 306 is 4 bits (address [3:0]). In some examples, the splitter 306 configures the least significant bits (LSB) of the memory address bus 316 to zero, because the memory address bus 316 is only to be indexed by a multiple of four (e.g., binary value “0000” is equivalent to decimal value “0”, binary value “0100” is equivalent to decimal value “4”, binary value “1000” is equivalent to decimal value “8”, binary value “1100” is equivalent to decimal value “12”), such as 4, 8, and 12. Therefore, the destination of the memory address bus 316 does not check the LSB of the 4-bit memory address bus 316. During synthesis, example synthesis circuitry (e.g., synthesis circuitry 102 of FIG. 1) floats the LSB because probes will not check the LSB.

In FIG. 3, the example bus unit 310 is to communicate commands and/or data from the example splitter 306 to a device that interfaces with the example SDIO controller 304. For example, the bus unit 310 is to direct commands and/or data from the splitter 306 to a device that is intended to receive such commands and/or data. In an example, the RTL for the interconnect block 302 and SDIO controller 304 are merely wrappers with respect to the command and data wires and do not specify any intervening logic between the splitter 306 and the bus unit 310.

However, in the associated GLN shown in FIG. 3, the example interconnect block 302 includes the first logic gate 308 coupled to the output of the splitter to help drive the signal along the physical wire, and similarly, the example SDIO controller 304 includes the second logic gate 312 coupled to the output of the first logic gate 308 and the input of the bus unit 310. The first and second logic gates 308, 312 are inverters. In some examples, the first and second logic gates 308, 312 were added to the GLN during optimization of the RTL code 114 (FIG. 1). The first logic gate 308 inverts an output of the splitter 306, and the second logic gate 312 inverts the output of the first logic gate 308 back to the initial output of the splitter 306. For example, in some iterations of the synthesis, inverting logic gates 308 and 312 are replaced by pairs of inverters (e.g., buffers), which has the effect of changing the logical value of some intermediate wires, although the value at the input of the bus unit 310 remains the same given a value at the output of the splitter 306. In this manner, the bus unit 310 is to obtain an output from the splitter 306 regardless of the number of inverters coupled in the wire path. For example, the splitter 306 includes a conditional statement indicating that if (a=b), then the value on the command line is “1.” In an example when the condition is met (e.g., when a=b), the splitter 306 is to output and 1 and the bus unit 310 receives the 1.

Although the command (e.g. data) delivered to the bus unit 310 is the same command output by the splitter 306, a probe on the command line may read a different output, depending on where the probe is placed and the number of inversions that occur along the wire path. For example, prior to implementing the probe selection controller 126, the development environment 100 (FIG. 1) placed a first initial probe 314a at the input of the second logic gate 312 (e.g., at the boundary of the SDIO controller 304). This first initial probe 314a placement read a “0” instead of a “1” if the condition was met (e.g., when a=b). The first initial probe 314a was reading and returning a value that is not what the splitter 306 outputs and additionally is not what the bus unit 310 actually receives during a desired behavior of the SoC.

Therefore, example tracing circuitry 206 modifies and/or changes the placement of the initial probe 314a to a location that has a low possibility of returning undesirable results. For example, the example tracing circuitry 206 takes the first initial probe 314a, identifies the equivalent wire connectivity in the RTL code 114 that the first initial probe 314a is placed on (e.g., CMD line), and analyzes the equivalent wire connectivity in the RTL code 114. The example tracing circuitry 206 traces the equivalent wire connectivity (e.g., nets, interconnections, wires, conductors, signal paths, inputs, outputs, etc.) from an end point to a beginning point. For example, the tracing circuitry 206 traces the wire connectivity (e.g., CMD line) from a current module (SDIO 304) to a source module (interconnect block 302) using the RTL code 114.

When a source module is identified, the example tracing circuitry 206 determines whether the wire connectivity connects to an output of another module (e.g., a gate or other circuit device). For example, the tracing circuitry 206 determines that the CMD line, at the boundary of the interconnect block 302, connects to an output of the splitter 306. In this example, the tracing circuitry 206 has determined that the wire connectivity connects to an output of another module. In some examples, the tracing circuitry 206 determines that there is not another module and, thus, the source module (e.g., interconnect block 302) of the CMD line is the root module (e.g., the module which has a root output, where the root output is driven internally from fixed (e.g., hardcoded) logic or a register) driving the output on the CMD line. The tracing circuitry 206 identifies the output of the root module as the alternative probe location, because that output is more predictable.

In FIG. 3, the example tracing circuitry 206 identifies a first module output at the output of the first logic gate 308 when tracing back the wire connectivity (e.g., CMD line) from the boundary of the interconnect block 302 to an output of the next module. The example tracing circuitry 206 repeats the steps of determining whether the wire connectivity connects to an output of another module and tracing back the wire connectivity from the source module (e.g., the most current module that the tracing circuitry 206 is analyzing, which is now the first logic gate 308 in this example) to an output of the next module (e.g., the output of the splitter 306). In some examples, the tracing circuitry 206 stops repeating these steps when the wire connectivity, at a particular module output, is not connected to another module output. For example, in FIG. 3, the tracing circuitry 206 stops tracing back the interconnection at the output of the splitter 306. The tracing circuitry 206 stops at the splitter 306 output because the splitter 306 does not receive an input from another module. Instead, the example splitter 306 is driven internally from fixed (e.g., hardcoded) logic or a register provides the initial output for the CMD line.

In this example, the tracing circuitry 206 determines that the splitter 306 is the root module for the wire connectivity (e.g., the CMD line). When the root module is identified, the example tracing circuitry 206 triggers the example assignment circuitry 208 (FIG. 2) to assign the alternative probe location based on the identified root module. For example, the tracing circuitry 206 triggers the assignment circuitry 208 to modify the placement of the first initial probe 314a to the alternative probe location 314b (e.g., the output of the splitter 306).

In another example, the tracing circuitry 206 finds an alternative probe location 318b for the memory address bus 316 verification bus probing 318a (second initial probe 318a). The example development environment 100 generated a second initial probe 318a for the memory address bus 316 during simulation and verification of RTL code (e.g., RTL code 114 of FIG. 1). The second initial probe 318a may have correctly probed the memory address bus 316 during RTL code simulation, but due to optimization changes, the second initial probe 318a may not correctly probe the memory address bus 316 during GLN simulation. The synthesis circuitry (e.g., synthesis circuitry 102 of FIG. 1) floats the LSB in the 4-bit memory address bus 316, causing a value of “HighZ” at the LSB on the destination module. In some examples, the “HighZ” value causes the second initial probe 318a to display and/or read the memory address bus 316 incorrectly. For example, the “HighZ” can create errors or glitches while the second initial probe 318a is trying to read the value of the memory address bus 316. Therefore, the example tracing circuitry 206 identifies an alternative probe location 318b for the second initial probe 318a.

The example tracing circuitry 206 selects the second initial probe 318a, identifies the equivalent wire connectivity in the RTL code 114 that the second initial probe 318a is placed on (e.g., CMD line), and analyzes the equivalent wire connectivity in the RTL code 114. The example tracing circuitry 206 traces the equivalent wire connectivity (e.g., nets, wire connectivity, wires, conductors, signal paths, inputs, outputs, etc.) from an end point to a beginning point. For example, the tracing circuitry 206 traces the wire connectivity (e.g., the memory address bus 316) from a current module (SDIO 304) to a source module (interconnect block 302) using the RTL code 114. When a source module is identified, the example tracing circuitry 206 determines whether the wire connectivity connects to an output of another module (e.g., a gate or other circuit device). For example, the tracing circuitry 206 determines that the memory address bus 316, at the boundary of the interconnect block 302, connects to an output of the splitter 306. In this example, the tracing circuitry 206 has determined that the wire connectivity connects to an output of another module. The example tracing circuitry 206 determines that there is not another module and, thus, the source module (e.g., splitter 306) of the memory address bus 316 is the root module (e.g., the module which has a root output, where the root output is driven internally from fixed (e.g., hardcoded) logic or a register) driving the output on the memory address bus 316. When the root module is identified, the example tracing circuitry 206 triggers the example assignment circuitry 208 (FIG. 2) to assign the alternative probe location 318b based on the identified root module. For example, the tracing circuitry 206 triggers the assignment circuitry 208 to modify the placement of the second initial probe 318a to the alternative probe location 318b (e.g., the output of the splitter 306).

Returning to FIG. 2, the example probe selection controller 126 of FIGS. 1 and 2 includes the example assignment circuitry 208 to assign the output of the root module as the probing point. For example, the assignment circuitry 208 determines that the alternative probe location for the CMD line in the GLS 300 of FIG. 3 is the output of the splitter 306. The example assignment circuitry 208 assigns an output of the example splitter 306 as the first alternative probe location 314b. The example assignment circuitry 208 stores the probing point assignment in the example probe datastore 108. For example, the assignment circuitry 208 stores information representative of the root module and the corresponding alternative probing point for that root module. The example assignment circuitry 208 stores alternative probing points for the initial probes, where the initial probes are placed at locations having a high probability of optimization issues. In some examples, the assignment circuitry 208 generates a report of the GLN 101, including root modules and corresponding alternative probing points. In such an example, the assignment circuitry 208 stores the report in the probe datastore 108. Such a report can be used by the example GLN simulation circuitry 110 and/or the example debugging circuitry 112 to change the probes on wire connectivity in the simulated GLN. In some examples, the GLN simulation circuitry 110 automatically uses the alternative probes and, thus, automatically replaces the initial probes, prior to simulation and debugging. In this example, the probe selection controller 126 reduces an amount of time spent debugging the GLS, because a test engineer does not need to spend time replacing/moving probe points to better locations on a given wire connectivity.

While an example manner of implementing the probe selection controller 126 of FIG. 1 is illustrated in FIG. 2, one or more of the elements, processes, and/or devices illustrated in FIG. 2 may be combined, divided, re-arranged, omitted, eliminated, and/or implemented in any other way. Further, the interface circuitry 202, the example parsing circuitry 204, the example tracing circuitry 206, the example assignment circuitry 208, and/or, more generally, the example probe selection controller 126 of FIG. 2, may be implemented by hardware alone or by hardware in combination with software and/or firmware. Thus, for example, any of the interface circuitry 202, the example parsing circuitry 204, the example tracing circuitry 206, the example assignment circuitry 208, and/or, more generally, the example probe selection controller 126, could be implemented by programmable circuitry in combination with machine readable instructions (e.g., firmware or software), processor circuitry, analog circuit(s), digital circuit(s), logic circuit(s), programmable processor(s), programmable microcontroller(s), graphics processing unit(s) (GPU(s)), digital signal processor(s) (DSP(s)), ASIC(s), programmable logic device(s) (PLD(s)), and/or field programmable logic device(s) (FPLD(s)) such as FPGAs. Further still, the example probe selection controller 126 of FIG. 2 may include one or more elements, processes, and/or devices in addition to, or instead of, those illustrated in FIG. 2, and/or may include more than one of any or all of the illustrated elements, processes and devices.

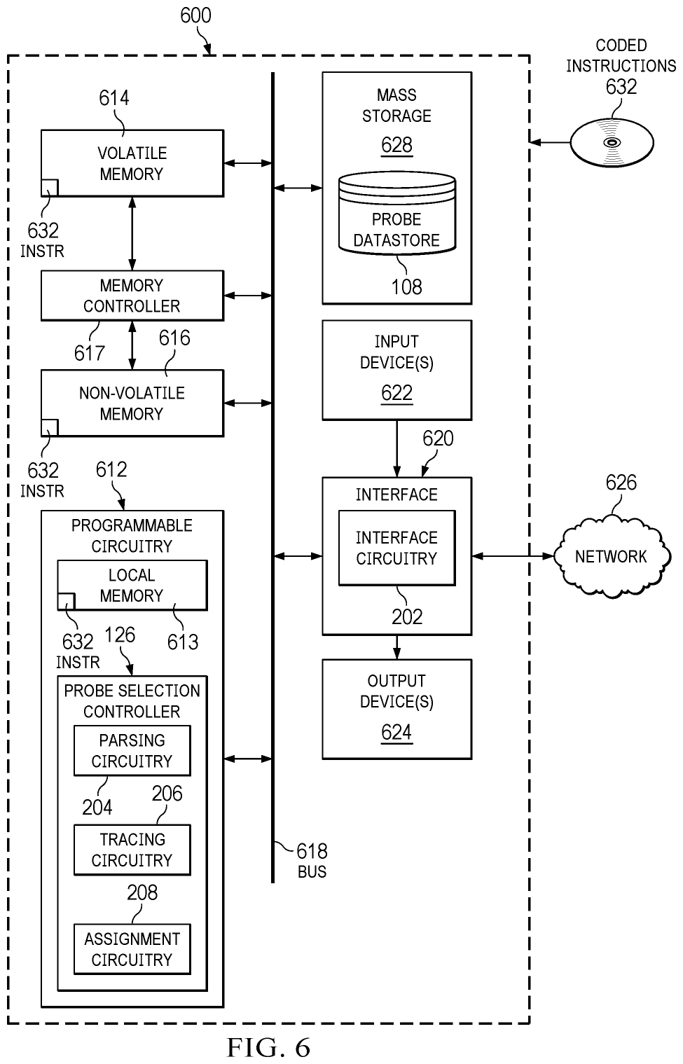

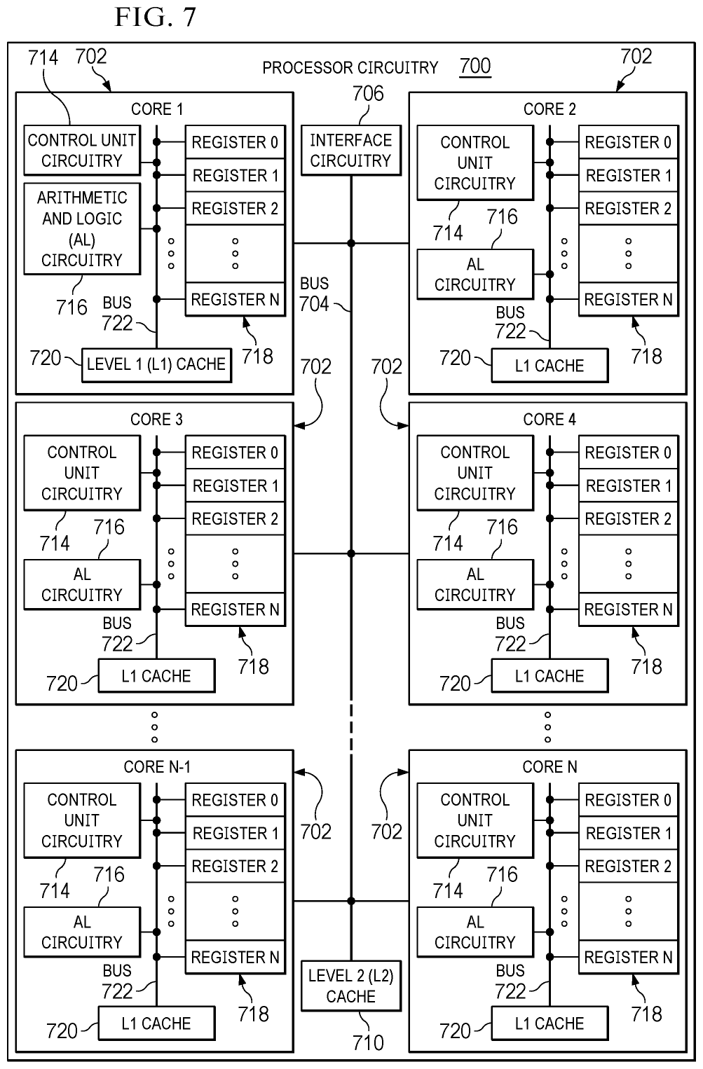

Flowcharts representative of example machine readable instructions, which may be executed by programmable circuitry to implement and/or instantiate the probe selection controller 126 of FIG. 2 and/or representative of example operations which may be performed by programmable circuitry to implement and/or instantiate the probe selection controller 126 of FIG. 2, are shown in FIGS. 4-5. The machine readable instructions may be one or more executable programs or portion(s) of one or more executable programs for execution by programmable circuitry such as the programmable circuitry 612 shown in the example processor platform 600 discussed below in connection with FIG. 6 and/or may be one or more function(s) or portion(s) of functions to be performed by the example programmable circuitry (e.g., an FPGA) discussed below in connection with FIGS. 7 and/or 8. In some examples, the machine readable instructions cause an operation, a task, etc., to be carried out and/or performed in an automated manner in the real world. As used herein, “automated” means without human involvement.

The program may be embodied in instructions (e.g., software and/or firmware) stored on one or more non-transitory computer readable and/or machine readable storage medium such as cache memory, a magnetic-storage device or disk (e.g., a floppy disk, a Hard Disk Drive (HDD), etc.), an optical-storage device or disk (e.g., a Blu-ray disk, a Compact Disk (CD), a Digital Versatile Disk (DVD), etc.), a Redundant Array of Independent Disks (RAID), a register, ROM, a solid-state drive (SSD), SSD memory, non-volatile memory (e.g., electrically erasable programmable read-only memory (EEPROM), flash memory, etc.), volatile memory (e.g., Random Access Memory (RAM) of any type, etc.), and/or any other storage device or storage disk. The instructions of the non-transitory computer readable and/or machine readable medium may program and/or be executed by programmable circuitry located in one or more hardware devices, but the entire program and/or parts thereof could alternatively be executed and/or instantiated by one or more hardware devices other than the programmable circuitry and/or embodied in dedicated hardware. The machine-readable instructions may be distributed across multiple hardware devices and/or executed by two or more hardware devices (e.g., a server and a client hardware device). For example, the client hardware device may be implemented by an endpoint client hardware device (e.g., a hardware device associated with a human and/or machine user) or an intermediate client hardware device gateway (e.g., a radio access network (RAN)) that may facilitate communication between a server and an endpoint client hardware device. Similarly, the non-transitory computer readable storage medium may include one or more mediums. Further, although the example program is described with reference to the flowcharts illustrated in FIGS. 4-5, many other methods of implementing the example probe selection controller 126 may alternatively be used. For example, the order of execution of the blocks of the flowcharts may be changed, and/or some of the blocks described may be changed, eliminated, or combined. Additionally or alternatively, any or all of the blocks of the flow chart may be implemented by one or more hardware circuits (e.g., processor circuitry, discrete and/or integrated analog and/or digital circuitry, an FPGA, an ASIC, a comparator, an operational-amplifier (op-amp), a logic circuit, etc.) structured to perform the corresponding operation without executing software or firmware. The programmable circuitry may be distributed in different network locations and/or local to one or more hardware devices (e.g., a single-core processor (e.g., a single core CPU), a multi-core processor (e.g., a multi-core CPU, an XPU, etc.)). For example, the programmable circuitry may be a CPU and/or an FPGA located in the same package (e.g., the same integrated circuit (IC) package or in two or more separate housings), one or more processors in a single machine, multiple processors distributed across multiple servers of a server rack, multiple processors distributed across one or more server racks, etc., and/or any combination(s) thereof.

The machine-readable instructions described herein may be stored in one or more of a compressed format, an encrypted format, a fragmented format, a compiled format, an executable format, a packaged format, etc. Machine readable instructions as described herein may be stored as data (e.g., computer-readable data, machine-readable data, one or more bits (e.g., one or more computer-readable bits, one or more machine-readable bits, etc.), a bitstream (e.g., a computer-readable bitstream, a machine-readable bitstream, etc.), etc.) or a data structure (e.g., as portion(s) of instructions, code, representations of code, etc.) that may be utilized to create, manufacture, and/or produce machine executable instructions. For example, the machine-readable instructions may be fragmented and stored on one or more storage devices, disks and/or computing devices (e.g., servers) located at the same or different locations of a network or collection of networks (e.g., in the cloud, in edge devices, etc.). The machine-readable instructions may require one or more of installation, modification, adaptation, updating, combining, supplementing, configuring, decryption, decompression, unpacking, distribution, reassignment, compilation, etc., in order to make them directly readable, interpretable, and/or executable by a computing device and/or other machine. For example, the machine readable instructions may be stored in multiple parts, which are individually compressed, encrypted, and/or stored on separate computing devices, wherein the parts when decrypted, decompressed, and/or combined form a set of computer-executable and/or machine executable instructions that implement one or more functions and/or operations that may together form a program such as that described herein.

In another example, the machine readable instructions may be stored in a state in which they may be read by programmable circuitry, but require addition of a library (e.g., a dynamic link library (DLL)), a software development kit (SDK), an application programming interface (API), etc., in order to execute the machine-readable instructions on a particular computing device or other device. In another example, the machine-readable instructions may need to be configured (e.g., settings stored, data input, network addresses recorded, etc.) before the machine readable instructions and/or the corresponding program(s) can be executed in whole or in part. Thus, machine readable, computer readable and/or machine-readable media, as used herein, may include instructions and/or program(s) regardless of the particular format or state of the machine-readable instructions and/or program(s).

The machine-readable instructions described herein can be represented by any past, present, or future instruction language, scripting language, programming language, etc. For example, the machine-readable instructions may be represented using any of the following languages: C, C++, Java, C#, Perl, Python, JavaScript, HyperText Markup Language (HTML), Structured Query Language (SQL), Swift, etc.

As mentioned above, the example operations of FIGS. 4-5 may be implemented using executable instructions (e.g., computer readable and/or machine-readable instructions) stored on one or more non-transitory computer readable and/or machine-readable media. As used herein, the terms non-transitory computer readable medium, non-transitory computer readable storage medium, non-transitory machine readable medium, and/or non-transitory machine-readable storage medium are expressly defined to include any type of computer readable storage device and/or storage disk and to exclude propagating signals and to exclude transmission media. Examples of such non-transitory computer readable medium, non-transitory computer readable storage medium, non-transitory machine readable medium, and/or non-transitory machine readable storage medium include optical storage devices, magnetic storage devices, an HDD, a flash memory, a read-only memory (ROM), a CD, a DVD, a cache, a RAM of any type, a register, and/or any other storage device or storage disk in which information is stored for any duration (e.g., for extended time periods, permanently, for brief instances, for temporarily buffering, and/or for caching of the information). As used herein, the terms “non-transitory computer readable storage device” and “non-transitory machine-readable storage device” are defined to include any physical (mechanical, magnetic and/or electrical) hardware to retain information for a time period, but to exclude propagating signals and to exclude transmission media. Examples of non-transitory computer readable storage devices and/or non-transitory machine-readable storage devices include random access memory of any type, read only memory of any type, solid state memory, flash memory, optical discs, magnetic disks, disk drives, and/or redundant array of independent disks (RAID) systems. As used herein, the term “device” refers to physical structure such as mechanical and/or electrical equipment, hardware, and/or circuitry that may or may not be configured by computer readable instructions, machine readable instructions, etc., and/or manufactured to execute computer-readable instructions, machine-readable instructions, etc.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a,” “an,” “first,” “second,” etc.) do not exclude a plurality. The term “a” or “an” object, as used herein, refers to one or more of that object. The terms “a” (or “an”), “one or more,” and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

FIG. 4 is a flowchart representative of example machine readable instructions and/or example operations 400 that may be executed, instantiated, and/or performed by programmable circuitry to generate alternative probes for a GLN. The example machine-readable instructions and/or the example operations 400 of FIG. 4 begin at block 402, at which the probe selection controller 126 (FIG. 1) determines whether a modification of probes request has been initiated. For example, the interface circuitry 202 (FIG. 2) waits to obtain a request from the development environment 100 and/or the probe selection controller 126 (FIG. 1) to modify probes. In some examples, the probe selection controller 126 triggers probe modification when the probe selection controller 126 obtains a GLN 101. For example, the probe selection controller 126 may intercept the GLN 101 before the GLN 101 is simulated.

At block 404, the example probe selection controller 126 obtains RTL code. For example, the interface circuitry 202 obtains RTL code 114. In some examples, the probe selection controller 126 uses the RTL code 114 to find and trace a wire connectivity having an initial probe that needs to be modified. In some examples, the probe selection controller 126 uses the RTL code 114 to identify modules (e.g., gates and other circuit devices) connected to a wire connectivity. For example, the tracing circuitry 206 uses the RTL code 114 to trace a wire connectivity and identify a root module connected to the wire connectivity.

At block 406, the example probe selection controller 126 parses the RTL code 114 to identify parameters and statements. For example, the parsing circuitry 204 extracts information representative of intended and/or actual connections of the modules in the GLN 101. In some examples, the parsing circuitry 204 extracts naming conventions of the modules, such as hierarchical naming conventions representative of a logical hierarchy of modules.

At block 408, the example probe selection controller 126 obtains initial probes from the example probe datastore 108 (FIG. 1). For example, the interface circuitry 202 requests initial probes generated during simulation of the RTL code 114, because the GLN simulation circuitry 110 uses the initial probes when simulating the GLN 101. The initial probes are problematic during simulation of the GLN 101 due to optimization changes of the RTL code 114 during synthesis.

At block 410, the example probe selection controller 126 modifies the initial probes based on the parsed RTL code 114. The operation of block 410 is described in further detail below in connection with FIG. 5.

At block 412, the example probe selection controller 126 notifies an engineer (e.g., software engineer, development engineer, design engineer, or any person, entity designing the target IC) that alternative probes are available. For example, the interface circuitry 202 may generate instructions that cause the development environment 100 to notify the engineer that alternative probes have been selected and stored for subsequent use.

At block 414, the example probe selection controller 126 determines whether an engineer has selected to use alternative probes. For example, the interface circuitry 202 may obtain a request to use the alternative probes in response to sending the notification that alternative probes are available.

At block 416, when the example probe selection controller 126 determines that an engineer has selected to use alternative probes (block 414 returns a value YES), the example probe selection controller 126 instructs the example GLN simulation circuitry 110 to use alternative probes. In some examples, the instruction to use alternative probes causes the GLN simulation circuitry 110 to load the alternative probes in the DV environment 100 prior to simulation of the GLN 101.

At block 418, when the example probe selection controller 126 determines that an engineer has not selected to use alternative probes (block 414 returns a value NO), the example probe selection controller 126 instructs the example GLN simulation circuitry 110 to use initial probes. In some examples, the instruction to use initial probes causes the GLN simulation circuitry 110 to simulate the GLN 101 as normal.

The example operations 400 end when the example probe selection controller 126 instructs the example GLN simulation circuitry 110 to use or not use alternative probes. The example operations 400 may be repeated when the example probe selection controller 126 obtains a new GLN.

FIG. 5 is a flowchart representative of example machine readable instructions and/or example operations 410 that may be executed, instantiated, and/or performed by programmable circuitry to modify the initial probes based on parsed RTL code 114. The example machine-readable instructions and/or the example operations 410 of FIG. 5 begin at block 502, at which the probe selection controller 126 (FIG. 1) selects an initial probe to analyze. For example, the tracing circuitry 206 (FIG. 2) iterates through a list of initial probes to analyze and modify, if needed. In some examples, an initial probe is at a location having a low probability of optimization issues and, thus, does not need to be modified. In some examples, the tracing circuitry 206 still traces the wire path of the probe (described in further detail below) to ensure that such an initial probe is at a location with greater predictability relative to initial probes placed at locations that have been optimized during synthesis.

At block 504, the example probe selection controller 126 identifies wire connectivity in the RTL code 114 that is equivalent to the wire connectivity the initial probe is probing. For example, the tracing circuitry 206 identifies which wire connectivity the selected initial probe is on, and then finds the equivalent wire connectivity in the RTL code 114. In some examples, the tracing circuitry 206 identifies a wire connectivity using the RTL code 114 and initial probe because the initial probe is a logical flag having a hierarchical naming convention to enable identification of the probes in the RTL code 114 and/or differentiate the probes from the modules. For example, the tracing circuitry 206 uses the name of the initial probe to determine parts (e.g., outputs of modules) of the GLN 101 that are probed.

At block 506, the example probe selection controller 126 determines whether the wire connectivity inputs to a module. For example, the tracing circuitry 206 determines the direction of the wire connectivity and whether the end of the wire connectivity connects to a module. In some examples, the tracing circuitry 206 determines whether the wire connectivity is connected between two modules to identify if the wire path is input into a module (e.g., gates and other circuit devices).

If the example probe selection controller 126 and/or the example tracing circuitry 206 determines that the wire connectivity inputs to a module (block 506 returns a value YES), then the example probe selection controller 126 traces back the wire connectivity from a current module to a source module (block 508). For example, the tracing circuitry 206 identifies the module that is receiving an input from the wire connectivity (e.g., the current module). Then the tracing circuitry 206 uses RTL code 114 (FIG. 1) to find the module (e.g., source module) sending the output, via the wire connectivity, to the current module. The RTL code 114 includes information representative of how modules are to interact and, thus, the tracing circuitry 206 can use such information to identify a source module connected, via the wire connectivity, to the current module.

If the example probe selection controller 126 and/or the example tracing circuitry 206 determines that the wire connectivity does not input to a module (block 506 returns a value NO), the example probe selection controller 126 determines that a root module is found for the wire connectivity (block 514). For example, the tracing circuitry 206 determines that the initial probe is at the output of the root module, where the output of the root source module is driven internally from fixed (e.g., hardcoded) logic or a register and has greater predictability relative to outputs that have been optimized during synthesis.

At block 510, the example probe selection controller 126 determines whether the wire connectivity at the source module connects to an output of another module. For example, the tracing circuitry 206 determines whether wire connectivity is an output of a low-level module of the current source module. In some examples, the source module is a submodule which includes low-level modules describing circuit components within the submodule, such as logic gates and other circuit devices. The wire connectivity may connect to an output of one of those low-level components. For example, the CMD line (FIG. 3) traces from the output of the interconnect block 302, which is a submodule, back to the output of the first logic gate 308, which is a low-level module. Then, the CMD line traces from the input of the first logic gate 308 back to the output of the splitter 306, which is also a low-level module of the interconnect block 302. The tracing circuitry 206 uses the RTL code 114 to determine whether the source module includes any low-level modules. The RTL code 114 provides the hardware description language (HDL) of the modules, which describe how the module connects to another module.

If the example probe selection controller 126 determines that the wire connectivity at the source module connects to an output of another module (block 510 returns a value YES), the example probe selection controller 126 traces back the wire connectivity from the current source module to the output of another module (block 512). For example, tracing circuitry 206 uses the RTL code 114 to identify the previous module (e.g., the first logic gate 308) on the wire connectivity (e.g., CMD line), where the previous module is the module outputting to the boundary of the current source module (e.g., the interconnect block 302). When the example tracing circuitry 206 traces the wire connectivity from the source module to the output of another module, control returns to block 510 and the steps 510 and 512 are repeated.

If the example probe selection controller 126 determines that the wire connectivity does not connect to an output of another module (block 510 returns a value NO), the example probe selection controller 126 determines that the root module is found for the wire connectivity (block 512). For example, the tracing circuitry 206 determines that the current source module is the root module. Referring to FIG. 3, the tracing circuitry 206 determines that the splitter 306 is the root module, because the splitter 306 is driven internally from fixed (e.g., hardcoded) logic or a register

At block 516, the example probe selection controller 126 assigns the output of the root module as the alternative probe. For example, the assignment circuitry 208 (FIG. 2) flags and/or tags the module as the root module. Then the example assignment circuitry 208 generates an alternative logical flag that probes the output of the root module.

At block 518, the example probe selection controller 126 stores the alternative probe in a database. For example, the assignment circuitry 208 stores the alternative probe in the probe datastore 108 (FIG. 1) and maps (e.g., associates) the alternative probe to the root module.

At block 520, the example probe selection controller 126 determines whether there is another initial probe. For example, the tracing circuitry 206 determines if there are any additional probes that should be modified.

If the example probe selection controller 126 determines there is another initial probe (block 520 returns a value YES), control returns to block 502. If the example probe selection controller 126 determines there is not another initial probe to modify (block 520 returns a value NO), the operations 410 end and control returns to block 412 of FIG. 4 (e.g., the probe selection controller 126 notifies engineer (FIG. 1) that alternative probes are available). The example operations 410 may be repeated when the probe selection controller 126 is triggered to modify probes prior to simulation of the GLN 101.

FIG. 6 is a block diagram of an example programmable circuitry platform 600 structured to execute and/or instantiate the example machine-readable instructions and/or the example operations of FIGS. 4-5 to implement the probe selection controller 126 of FIG. 2. The programmable circuitry platform 600 can be, for example, a server, a personal computer, a workstation, a self-learning machine (e.g., a neural network or any other type of computing and/or electronic device.

The programmable circuitry platform 600 of the illustrated example includes programmable circuitry 612. The programmable circuitry 612 of the illustrated example is hardware. For example, the programmable circuitry 612 can be implemented by one or more integrated circuits, logic circuits, FPGAs, microprocessors, CPUs, GPUs, DSPs, and/or microcontrollers from any desired family or manufacturer. The programmable circuitry 612 may be implemented by one or more semiconductor based (e.g., silicon based) devices. In this example, the programmable circuitry 612 implements the probe selection controller 126, the parsing circuitry 204, the tracing circuitry 206, and the assignment circuitry 208.

The programmable circuitry 612 of the illustrated example includes a local memory 613 (e.g., a cache, registers, etc.). The programmable circuitry 612 of the illustrated example is in communication with main memory 614, 616, which includes a volatile memory 614 and a non-volatile memory 616, by a bus 618. The volatile memory 614 may be implemented by Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 616 may be implemented by flash memory and/or any other desired type of memory device. Access to the main memory 614, 616 of the illustrated example is controlled by a memory controller 617. In some examples, the memory controller 617 may be implemented by one or more integrated circuits, logic circuits, microcontrollers from any desired family or manufacturer, or any other type of circuitry to manage the flow of data going to and from the main memory 614, 616.

The programmable circuitry platform 600 of the illustrated example also includes interface circuitry 620. The interface circuitry 620 may be implemented by hardware in accordance with any type of interface standard, such as an Ethernet interface, a universal serial bus (USB) interface, a Bluetooth® interface, a near field communication (NFC) interface, a Peripheral Component Interconnect (PCI) interface, and/or a Peripheral Component Interconnect Express (PCIe) interface. In this example, the interface circuitry 620 implements the interface circuitry 202.

In the illustrated example, one or more input devices 622 are connected to the interface circuitry 620. The input device(s) 622 permit(s) a user (e.g., a human user, a machine user, etc.) to enter data and/or commands into the programmable circuitry 612. The input device(s) 622 can be implemented by, for example, a keyboard, a button, a mouse, a touchscreen, a trackpad, a trackball, and/or an isopoint device, and/or a voice recognition system.

One or more output devices 624 are also connected to the interface circuitry 620 of the illustrated example. The output device(s) 624 can be implemented, for example, by display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, and/or speaker. The interface circuitry 620 of the illustrated example, thus, typically includes a graphics driver card, a graphics driver chip, and/or graphics processor circuitry such as a GPU.

The interface circuitry 620 of the illustrated example also includes a communication device such as a transmitter, a receiver, a transceiver, a modem, a residential gateway, a wireless access point, and/or a network interface to facilitate exchange of data with external machines (e.g., computing devices of any kind) by a network 626. The communication can be by, for example, an Ethernet connection, a digital subscriber line (DSL) connection, a telephone line connection, a coaxial cable system, a satellite system, a beyond-line-of-sight wireless system, a line-of-sight wireless system, a cellular telephone system, an optical connection, etc.

The programmable circuitry platform 600 of the illustrated example also includes one or more mass storage discs or devices 628 to store firmware, software, and/or data. Examples of such mass storage discs or devices 628 include magnetic storage devices (e.g., floppy disk, drives, HDDs, etc.), optical storage devices (e.g., Blu-ray disks, CDs, DVDs, etc.), RAID systems, and/or solid-state storage discs or devices such as flash memory devices and/or SSDs. In this example, the mass storage discs or devices 628 implements the probe datastore 108.

The machine readable instructions 632, which may be implemented by the machine readable instructions of FIGS. 4-5, may be stored in the mass storage device 628, in the volatile memory 614, in the non-volatile memory 616, and/or on at least one non-transitory computer readable storage medium such as a CD or DVD which may be removable.

FIG. 7 is a block diagram of an example implementation of the programmable circuitry 612 of FIG. 6. In this example, the programmable circuitry 612 of FIG. 6 is implemented by a microprocessor 700. For example, the microprocessor 700 may be a general-purpose microprocessor (e.g., general-purpose microprocessor circuitry). The microprocessor 700 executes some or all of the machine-readable instructions of the flowcharts of FIGS. 4-5 to effectively instantiate the circuitry of FIG. 2 as logic circuits to perform operations corresponding to those machine-readable instructions. In some such examples, the circuitry of FIG. 2 is instantiated by the hardware circuits of the microprocessor 700 in combination with the machine-readable instructions. For example, the microprocessor 700 may be implemented by multi-core hardware circuitry such as a CPU, a DSP, a GPU, an XPU, etc. Although it may include any number of example cores 702 (e.g., 1 core), the microprocessor 700 of this example is a multi-core semiconductor device including N cores. The cores 702 of the microprocessor 700 may operate independently or may cooperate to execute machine readable instructions. For example, machine code corresponding to a firmware program, an embedded software program, or a software program may be executed by one of the cores 702 or may be executed by multiple ones of the cores 702 at the same or different times. In some examples, the machine code corresponding to the firmware program, the embedded software program, or the software program is split into threads and executed in parallel by two or more of the cores 702. The software program may correspond to a portion or all of the machine-readable instructions and/or operations represented by the flowcharts of FIGS. 4-5.

The cores 702 may communicate by a first example bus 704. In some examples, the first bus 704 may be implemented by a communication bus to effectuate communication associated with one(s) of the cores 702. For example, the first bus 704 may be implemented by at least one of an Inter-Integrated Circuit (I2C) bus, a Serial Peripheral Interface (SPI) bus, a PCI bus, or a PCIe bus. Additionally or alternatively, the first bus 704 may be implemented by any other type of computing or electrical bus. The cores 702 may obtain data, instructions, and/or signals from one or more external devices by example interface circuitry 706. The cores 702 may output data, instructions, and/or signals to the one or more external devices by the interface circuitry 706. Although the cores 702 of this example include example local memory 720 (e.g., Level 1 (L1) cache that may be split into an L1 data cache and an L1 instruction cache), the microprocessor 700 also includes example shared memory 710 that may be shared by the cores (e.g., Level 2 (L2 cache)) for high-speed access to data and/or instructions. Data and/or instructions may be transferred (e.g., shared) by writing to and/or reading from the shared memory 710. The local memory 720 of each of the cores 702 and the shared memory 710 may be part of a hierarchy of storage devices including multiple levels of cache memory and the main memory (e.g., the main memory 614, 616 of FIG. 6). Typically, higher levels of memory in the hierarchy exhibit lower access time and have smaller storage capacity than lower levels of memory. Changes in the various levels of the cache hierarchy are managed (e.g., coordinated) by a cache coherency policy.

Each core 702 may be referred to as a CPU, DSP, GPU, etc., or any other type of hardware circuitry. Each core 702 includes control unit circuitry 714, arithmetic and logic (AL) circuitry (sometimes referred to as an ALU) 716, a plurality of registers 718, the local memory 720, and a second example bus 722. Other structures may be present. For example, each core 702 may include vector unit circuitry, single instruction multiple data (SIMD) unit circuitry, load/store unit (LSU) circuitry, branch/jump unit circuitry, floating-point unit (FPU) circuitry, etc. The control unit circuitry 714 includes semiconductor-based circuits structured to control (e.g., coordinate) data movement within the corresponding core 702. The AL circuitry 716 includes semiconductor-based circuits structured to perform one or more mathematic and/or logic operations on the data within the corresponding core 702. The AL circuitry 716 of some examples performs integer-based operations. In other examples, the AL circuitry 716 also performs floating-point operations. In yet other examples, the AL circuitry 716 may include first AL circuitry that performs integer-based operations and second AL circuitry that performs floating-point operations. In some examples, the AL circuitry 716 may be referred to as an Arithmetic Logic Unit (ALU).

The registers 718 are semiconductor-based structures to store data and/or instructions such as results of one or more of the operations performed by the AL circuitry 716 of the corresponding core 702. For example, the registers 718 may include vector register(s), SIMD register(s), general-purpose register(s), flag register(s), segment register(s), machine-specific register(s), instruction pointer register(s), control register(s), debug register(s), memory management register(s), machine check register(s), etc. The registers 718 may be arranged in a bank as shown in FIG. 7. Alternatively, the registers 718 may be organized in any other arrangement, format, or structure, such as by being distributed throughout the core 702 to shorten access time. The second bus 722 may be implemented by at least one of an I2C bus, a SPI bus, a PCI bus, or a PCIe bus.

Each core 702 and/or, more generally, the microprocessor 700 may include additional and/or alternate structures to those shown and described above. For example, one or more clock circuits, one or more power supplies, one or more power gates, one or more cache home agents (CHAs), one or more converged/common mesh stops (CMSs), one or more shifters (e.g., barrel shifter(s)) and/or other circuitry may be present. The microprocessor 700 is a semiconductor device fabricated to include many transistors interconnected to implement the structures described above in one or more integrated circuits (ICs) contained in one or more packages.

The microprocessor 700 may include and/or cooperate with one or more accelerators (e.g., acceleration circuitry, hardware accelerators, etc.). In some examples, accelerators are implemented by logic circuitry to perform certain tasks more quickly and/or efficiently than can be done by a general-purpose processor. Examples of accelerators include ASICs and FPGAs such as those discussed herein. A GPU, DSP and/or other programmable device can also be an accelerator. Accelerators may be on-board the microprocessor 700, in the same chip package as the microprocessor 700 and/or in one or more separate packages from the microprocessor 700.

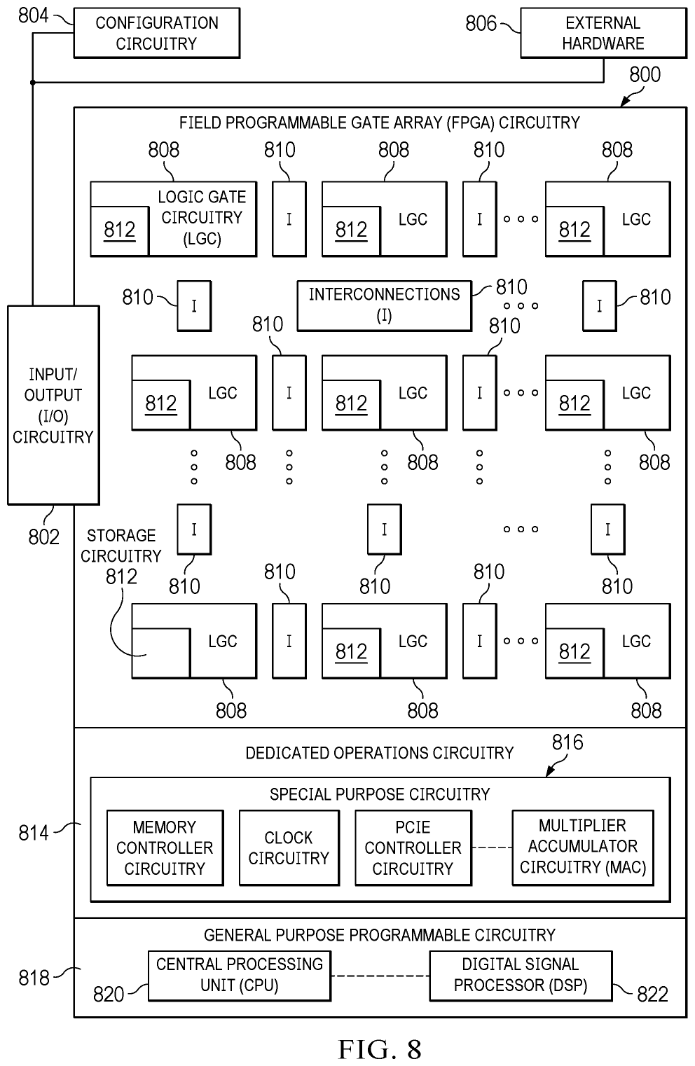

FIG. 8 is a block diagram of another example implementation of the programmable circuitry 612 of FIG. 6. In this example, the programmable circuitry 612 is implemented by FPGA circuitry 800. For example, the FPGA circuitry 800 may be implemented by an FPGA. The FPGA circuitry 800 can be used, for example, to perform operations that could otherwise be performed by the example microprocessor 700 of FIG. 7 executing corresponding machine-readable instructions. However, once configured, the FPGA circuitry 800 instantiates the operations and/or functions corresponding to the machine-readable instructions in hardware and, thus, can often execute the operations/functions faster than they could be performed by a general-purpose microprocessor executing the corresponding software.

More specifically, in contrast to the microprocessor 700 of FIG. 7 described above (which is a general purpose device that may be programmed to execute some or all of the machine readable instructions represented by the flowcharts of FIGS. 4-5 but whose interconnections and logic circuitry are fixed once fabricated), the FPGA circuitry 800 of the example of FIG. 8 includes interconnections and logic circuitry that may be configured, structured, programmed, and/or interconnected in different ways after fabrication to instantiate, for example, some or all of the operations/functions corresponding to the machine readable instructions represented by the flowcharts of FIGS. 4-5. In particular, the FPGA circuitry 800 may be thought of as an array of logic gates, interconnections, and switches. The switches can be programmed to change how the logic gates are interconnected by the interconnections, effectively forming one or more dedicated logic circuits (unless and until the FPGA circuitry 800 is reprogrammed). The configured logic circuits enable the logic gates to cooperate in different ways to perform different operations on data received by input circuitry. Those operations may correspond to some or all of the instructions (e.g., the software and/or firmware) represented by the flowcharts of FIGS. 4-5. As such, the FPGA circuitry 800 may be configured and/or structured to effectively instantiate some or all of the operations/functions corresponding to the machine-readable instructions of the flowcharts of FIGS. 4-5 as dedicated logic circuits to perform the operations/functions corresponding to those software instructions in a dedicated manner analogous to an ASIC. Therefore, the FPGA circuitry 800 may perform the operations/functions corresponding to the some or all of the machine-readable instructions of FIGS. 4-5 faster than the general-purpose microprocessor can execute the same.

In the example of FIG. 8, the FPGA circuitry 800 is configured and/or structured in response to being programmed (and/or reprogrammed one or more times) based on a binary file. In some examples, the binary file may be compiled and/or generated based on instructions in a hardware description language (HDL) such as Lucid, Very High Speed Integrated Circuits (VHSIC) Hardware Description Language (VHDL), or Verilog. For example, a user (e.g., a human user, a machine user, etc.) may write code or a program corresponding to one or more operations/functions in an HDL; the code/program may be translated into a low-level language as needed; and the code/program (e.g., the code/program in the low-level language) may be converted (e.g., by a compiler, a software application, etc.) into the binary file. In some examples, the FPGA circuitry 800 of FIG. 8 may access and/or load the binary file to cause the FPGA circuitry 800 of FIG. 8 to be configured and/or structured to perform the one or more operations/functions. For example, the binary file may be implemented by a bit stream (e.g., one or more computer-readable bits, one or more machine-readable bits, etc.), data (e.g., computer-readable data, machine-readable data, etc.), and/or machine-readable instructions accessible to the FPGA circuitry 800 of FIG. 8 to cause configuration and/or structuring of the FPGA circuitry 800 of FIG. 8, or portion(s) thereof.

In some examples, the binary file is compiled, generated, transformed, and/or otherwise output from a uniform software platform utilized to program FPGAs. For example, the uniform software platform may translate first instructions (e.g., code or a program) that correspond to one or more operations/functions in a high-level language (e.g., C, C++, Python, etc.) into second instructions that correspond to the one or more operations/functions in an HDL. In some such examples, the binary file is compiled, generated, and/or otherwise output from the uniform software platform based on the second instructions. In some examples, the FPGA circuitry 800 of FIG. 8 may access and/or load the binary file to cause the FPGA circuitry 800 of FIG. 8 to be configured and/or structured to perform the one or more operations/functions. For example, the binary file may be implemented by a bit stream (e.g., one or more computer-readable bits, one or more machine-readable bits, etc.), data (e.g., computer-readable data, machine-readable data, etc.), and/or machine-readable instructions accessible to the FPGA circuitry 800 of FIG. 8 to cause configuration and/or structuring of the FPGA circuitry 800 of FIG. 8, or portion(s) thereof.

The FPGA circuitry 800 of FIG. 8, includes example input/output (I/O) circuitry 802 to obtain and/or output data to/from example configuration circuitry 804 and/or external hardware 806. For example, the configuration circuitry 804 may be implemented by interface circuitry that may obtain a binary file, which may be implemented by a bit stream, data, and/or machine-readable instructions, to configure the FPGA circuitry 800, or portion(s) thereof. In some such examples, the configuration circuitry 804 may obtain the binary file from a user, a machine (e.g., hardware circuitry (e.g., programmable or dedicated circuitry) that may implement an Artificial Intelligence/Machine Learning (AI/ML) model to generate the binary file), etc., and/or any combination(s) thereof). In some examples, the external hardware 806 may be implemented by external hardware circuitry. For example, the external hardware 806 may be implemented by the microprocessor 700 of FIG. 7.

The FPGA circuitry 800 also includes an array of example logic gate circuitry 808, a plurality of example configurable interconnections 810, and example storage circuitry 812. The logic gate circuitry 808 and the configurable interconnections 810 are configurable to instantiate one or more operations/functions that may correspond to at least some of the machine-readable instructions of FIGS. 4-5 and/or other desired operations. The logic gate circuitry 808 shown in FIG. 8 is fabricated in blocks or groups. Each block includes semiconductor-based electrical structures that may be configured into logic circuits. In some examples, the electrical structures include logic gates (e.g., And gates, Or gates, Nor gates, etc.) that provide basic building blocks for logic circuits. Electrically controllable switches (e.g., transistors) are present within each of the logic gate circuitry 808 to enable configuration of the electrical structures and/or the logic gates to form circuits to perform desired operations/functions. The logic gate circuitry 808 may include other electrical structures such as look-up tables (LUTs), registers (e.g., flip-flops or latches), multiplexers, etc.

The configurable interconnections 810 of the illustrated example are conductive pathways, traces, vias, or the like that may include electrically controllable switches (e.g., transistors) whose state can be changed by programming (e.g., using an HDL instruction language) to activate or deactivate one or more connections between one or more of the logic gate circuitry 808 to program desired logic circuits.

The storage circuitry 812 of the illustrated example is structured to store result(s) of the one or more of the operations performed by corresponding logic gates. The storage circuitry 812 may be implemented by registers or the like. In the illustrated example, the storage circuitry 812 is distributed amongst the logic gate circuitry 808 to facilitate access and increase execution speed.

The example FPGA circuitry 800 of FIG. 8 also includes example dedicated operations circuitry 814. In this example, the dedicated operations circuitry 814 includes special purpose circuitry 816 that may be invoked to implement commonly used functions to avoid the need to program those functions in the field. Examples of such special purpose circuitry 816 include memory (e.g., DRAM) controller circuitry, PCIe controller circuitry, clock circuitry, transceiver circuitry, memory, and multiplier-accumulator circuitry. Other types of special purpose circuitry may be present. In some examples, the FPGA circuitry 800 may also include example general purpose programmable circuitry 818 such as an example CPU 820 and/or an example DSP 822. Other general purpose programmable circuitry 818 may additionally or alternatively be present such as a GPU, an XPU, etc., that can be programmed to perform other operations.

Although FIGS. 7 and 8 illustrate two example implementations of the programmable circuitry 612 of FIG. 6, many other approaches are contemplated. For example, FPGA circuitry may include an on-board CPU, such as one or more of the example CPU 820 of FIG. 7. Therefore, the programmable circuitry 612 of FIG. 6 may additionally be implemented by combining at least the example microprocessor 700 of FIG. 7 and the example FPGA circuitry 800 of FIG. 8. In some such hybrid examples, one or more cores 702 of FIG. 7 may execute a first portion of the machine readable instructions represented by the flowcharts of FIGS. 4-5 to perform first operation(s)/function(s), the FPGA circuitry 800 of FIG. 8 may be configured and/or structured to perform second operation(s)/function(s) corresponding to a second portion of the machine readable instructions represented by the flowcharts of FIG. 4-5, and/or an ASIC may be configured and/or structured to perform third operation(s)/function(s) corresponding to a third portion of the machine readable instructions represented by the flowcharts of FIGS. 4-5.

It should be understood that some or all of the circuitry of FIG. 2 may, thus, be instantiated at the same or different times. For example, same and/or different portion(s) of the microprocessor 700 of FIG. 7 may be programmed to execute portion(s) of machine-readable instructions at the same and/or different times. In some examples, same and/or different portion(s) of the FPGA circuitry 800 of FIG. 8 may be configured and/or structured to perform operations/functions corresponding to portion(s) of machine-readable instructions at the same and/or different times.

In some examples, some or all of the circuitry of FIG. 2 may be instantiated, for example, in one or more threads executing concurrently and/or in series. For example, the microprocessor 700 of FIG. 7 may execute machine readable instructions in one or more threads executing concurrently and/or in series. In some examples, the FPGA circuitry 800 of FIG. 8 may be configured and/or structured to carry out operations/functions concurrently and/or in series. Moreover, in some examples, some or all of the circuitry of FIG. 2 may be implemented within one or more virtual machines and/or containers executing on the microprocessor 700 of FIG. 7.

In some examples, the programmable circuitry 612 of FIG. 6 may be in one or more packages. For example, the microprocessor 700 of FIG. 7 and/or the FPGA circuitry 800 of FIG. 8 may be in one or more packages. In some examples, an XPU may be implemented by the programmable circuitry 612 of FIG. 6, which may be in one or more packages. For example, the XPU may include a CPU (e.g., the microprocessor 700 of FIG. 7, the CPU 820 of FIG. 8, etc.) in one package, a DSP (e.g., the DSP 822 of FIG. 8) in another package, a GPU in yet another package, and an FPGA (e.g., the FPGA circuitry 800 of FIG. 8) in still yet another package.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art.

As used herein “substantially real time” refers to occurrence in a near instantaneous manner recognizing there may be real world delays for computing time, transmission, etc. Thus, unless otherwise specified, “substantially real time” refers to real time+1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

From the foregoing, it will be appreciated that example systems, apparatus, articles of manufacture, and methods have been disclosed that improve the simulation of a gate level netlist by generating probes to monitor outputs having a low probability of optimization issues. Disclosed methods and apparatus improve the efficiency of using a computing device by reducing an amount of time it takes a computing device to execute a simulation of a gate level netlist. Disclosed apparatus and methods are accordingly directed to one or more improvement(s) in the operation of a machine such as a computer or other electronic and/or mechanical device.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. An apparatus comprising:
interface circuitry to obtain register transfer level code indicative of an operation of an integrated circuit;
machine-readable instructions; and
programmable circuitry to at least one of instantiate or execute the machine-readable instructions to:
obtain a gate level netlist corresponding to the integrated circuit, the gate level netlist including modules in the integrated circuit and connections between the modules;
obtain a first probe, the first probe representing a first location within the gate level netlist at which to monitor behavior;
identify a root module that includes an output configured to determine a signal at the first location; and
generate a second probe to replace the first probe representing a second location within the gate level netlist closer to the output of the root module than the first probe.

2. The apparatus of claim 1, wherein the programmable circuitry is to identify the root module by:
selecting the first probe;
identifying a first connection of the connections to trace based on the first location of the first probe;
tracing the first connection to determine that the first connection is an input to a first module;
identifying a source module of the first module, the source module including a first output configured to determine the signal at the first location; and
determining that the source module is the root module of the first connection.

3. The apparatus of claim 2, wherein the programmable circuitry is to replace the first probe with the second probe representing the second location that is closer to the output of the root module.

4. The apparatus of claim 1, wherein the programmable circuitry is to identify the root module by:
selecting a first connection of the connections to trace based on the first location of the first probe;
tracing the first connection to determine that the first connection is an input to a first module;
identifying a source module of the first module based on tracing the first connection from the first module back to the source module, the source module including a first output configured to provide the signal at the first location;
determining that the first connection at the source module connects an input of the source module to an output of a second module based on tracing the first connection from the input of the source module back to the output of the second module; and
assigning the second module as the root module of the first connection when the first connection does not trace back to an additional module.

5. The apparatus of claim 1, wherein the integrated circuit is an integrated circuit created according to the register transfer level code and the gate level netlist.

6. The apparatus of claim 1, wherein the programmable circuitry is to identify the root module by:
selecting the first probe;
identifying a first connection of the connections to trace based on the first location of the first probe;
tracing the first connection to determine that the first connection is an input to a first module;
identifying a source module of the first module, the source module including a first output configured to provide the signal at the first location;
determining that the first connection at the source module connects an input of the source module to an output of a second module based on tracing the first connection from the input of the source module back to the output of the second module;
determining that the first connection at the second module connects an input of the second module to an output of a third module based on tracing the first connection from the input of the second module back to the output of the third module; and
assigning the third module as the root module of the first connection when the first connection does not trace back to an additional module.

7. The apparatus of claim 1, wherein the programmable circuitry is to obtain the first probe from the interface circuitry, wherein the first probe is generated during a simulation of register transfer level code to monitor a behavior of logical parameters of the register transfer level code.

8. A method comprising:
obtaining register transfer level code indicative of an operation of an integrated circuit;
obtaining a gate level netlist corresponding to the integrated circuit, the gate level netlist including modules in the integrated circuit and connections between the modules;
obtaining a first probe, the first probe representing a first location within the gate level netlist at which to monitor behavior;
identifying a root module that includes an output configured to determine a signal at the first location; and
generating a second probe to replace the first probe representing a second location within the gate level netlist closer to the output of the root module than the first probe.

9. The method of claim 8, wherein identifying the root module includes:
selecting the first probe;
identifying a first connection of the connections to trace based on the first location of the first probe;
tracing the first connection to determine that the first connection is an input to a first module;
identifying a source module of the first module, the source module including a first output configured to determine the signal at the first location; and
determining that the source module is the root module of the first connection.

10. The method of claim 9, further including replacing the first probe with the second probe representing the second location that is closer to the output of the root module.

11. The method of claim 8, wherein identifying the root module includes:
selecting a first connection of the connections to trace based on the first location of the first probe;
tracing the first connection to determine that the first connection is an input to a first module;
identifying a source module of the first module based on tracing the first connection from the first module back to the source module, the source module including a first output configured to provide the signal at the first location;
determining that the first connection at the source module connects an input of the source module to an output of a second module based on tracing the first connection from the input of the source module back to the output of the second module; and
assigning the second module as the root module of the first connection when the first connection does not trace back to an additional module.

12. The method of claim 8, wherein the integrated circuit is an integrated circuit created according to the register transfer level code and the gate level netlist.

13. The method of claim 8, wherein identifying the root module includes:
selecting the first probe;
identifying a first connection of the connections to trace based on the first location of the first probe;
tracing the first connection to determine that the first connection is an input to a first module;
identifying a source module of the first module, the source module including a first output configured to provide the signal at the first location;
determining that the first connection at the source module connects an input of the source module to an output of a second module based on tracing the first connection from the input of the source module back to the output of the second module;
determining that the first connection at the second module connects an input of the second module to an output of a third module based on tracing the first connection from the input of the second module back to the output of the third module; and
assigning the third module as the root module of the first connection when the first connection does not trace back to an additional module.

14. The method of claim 8, further including obtaining the first probe from interface circuitry, wherein the first probe is generated during a simulation of register transfer level code to monitor a behavior of logical parameters of the register transfer level code.

15. A non-transitory machine-readable storage medium comprising instructions to cause programmable circuitry to at least:
obtain register transfer level code indicative of an operation of an integrated circuit;
obtain a gate level netlist corresponding to the integrated circuit, the gate level netlist including modules in the integrated circuit and connections between the modules;
obtain a first probe, the first probe representing a first location within the gate level netlist at which to monitor behavior;
identify a root module that includes an output configured to determine a signal at the first location; and
generate a second probe to replace the first probe representing a second location within the gate level netlist closer to the output of the root module than the first probe.

16. The non-transitory machine-readable storage medium of claim 15, wherein the instructions are to cause the programmable circuitry to identify the root module by:
selecting a first connection of the connections to trace based on the first location of the first probe;
tracing the first connection to determine that the first connection is an input to a first module;
identifying a source module of the first module based on tracing the first connection from the first module back to the source module, the source module including a first output configured to determine the signal at the first location; and
determining that the source module is the root module of the first connection.

17. The non-transitory machine-readable storage medium of claim 16, wherein the instructions are to cause the programmable circuitry to replace the first probe with the second probe representing the second location that is closer to the output of the root module.

18. The non-transitory machine-readable storage medium of claim 15, wherein the instructions are to cause the programmable circuitry to identify the root module by:
selecting the first probe;
identifying a first connection of the connections to trace based on the first location of the first probe;
tracing the first connection to determine that the first connection is an input to a first module;
identifying a source module of the first module, the source module including a first output configured to determine the signal at the first location;
determining that the first connection at the source module connects an input of the source module to an output of a second module based on tracing the first connection from the input of the source module back to the output of the second module; and
assigning the second module as the root module of the first connection when the first connection does not trace back to an additional module.

19. The non-transitory machine-readable storage medium of claim 15, wherein the instructions are to cause the programmable circuitry to identify the root module by:
selecting the first probe;
identifying a first connection of the connections to trace based on the first location of the first probe;
tracing the first connection to determine that the first connection is an input to a first module;
identifying a source module of the first module, the source module including a first output configured to provide the signal at the first location;
determining that the first connection at the source module connects an input of the source module to an output of a second module based on tracing the first connection from the input of the source module back to the output of the second module;
determining that the first connection at the second module connects an input of the second module to an output of a third module based on tracing the first connection from the input of the second module back to the output of the third module; and
assigning the third module as the root module of the first connection when the first connection does not trace back to an additional module.

20. The non-transitory machine-readable storage medium of claim 15, wherein the instructions are to cause the programmable circuitry to obtain the first probe from interface circuitry, wherein the first probe is generated during a simulation of register transfer level code to monitor a behavior of logical parameters of the register transfer level code.
